(19) United States
(12) Patent Application Publication
(10) Pub. No.: US 2014/0317337 A1
(43) Pub. Date: Oct. 23, 2014

(54) METADATA MANAGEMENT AND SUPPORT FOR PHASE CHANGE MEMORY WITH SWITCH (PCMS)

(71) Applicants: Leena K. Puthiyedath, Beaverton, OR (US); Marc T. Jones, Longmont, CO (US); R. Scott Tetrick, Portland, OR (US); Robert J. Royer, Jr., Portland, OR (US); Raj K. Ramanujan, Federal Way, WA (US); Glenn J. Hinton, Portland, OR (US); Blaise Fanning, Folsom, CA (US); Robert S. Gittins, Divide, CO (US); Mark A. Schmisseur, Phoenix, AZ (US); Frank T. Hady, Portland, OR (US); Robert W. Faber, Hillsboro, OR (US)

(72) Inventors: Leena K. Puthiyedath, Beaverton, OR (US); Marc T. Jones, Longmont, CO (US); R. Scott Tetrick, Portland, OR (US); Robert J. Royer, Jr., Portland, OR (US); Raj K. Ramanujan, Federal Way, WA (US); Glenn J. Hinton, Portland, OR (US); Blaise Fanning, Folsom, CA (US); Robert S. Gittins, Divide, CO (US); Mark A. Schmisseur, Phoenix, AZ (US); Frank T. Hady, Portland, OR (US); Robert W. Faber, Hillsboro, OR (US)

(21) Appl. No.: 13/997,215

(22) PCT Filed: Dec. 30, 2011
(86) PCT No.: PCT/US11/68040

§ 371 Date: Jul. 1, 2014

(51) Int. Cl. G11C 16/34; G11C 14/00; G06F 12/02

(52) U.S. Cl. CPC G11C 16/3431; G06F 12/0246; G11C 14/0045
USPC 711/103

(57) ABSTRACT

Methods and apparatus related to management and/or support of metadata for PCMS (Phase Change Memory with Switch) devices are described. In one embodiment, a PCMS controller allows access to a PCMS device based on metadata. The metadata may be used to provide efficiency, endurance, error correction, etc. as discussed in the disclosure. Other embodiments are also disclosed and claimed.

### FIELD

The present disclosure generally relates to the field of electronics. More particularly, some embodiments of the invention generally relate to management and/or support of metadata for PCMS (Phase Change Memory with Switch) devices.

### BACKGROUND

As processing capabilities are enhanced in processors, one concern is the speed at which memory may be accessed by a processor. For example, to process data, a processor may need to first fetch data from a memory. After completion of the processing, the results may need to be stored in the memory. Therefore, the memory speed can have a direct effect on overall system performance.

Another important consideration is power consumption. For example, in mobile computing devices that rely on battery power, it is very important to reduce power consumption to allow for the device to operate while mobile. Power consumption is also important for non-mobile computing devices as excess power consumption may increase costs (e.g., due to additional power usage, increasing cooling requirements, etc.), shorten component life, limit locations at which a device may be used, etc.

Hard disk drives provide a relatively low-cost storage solution and are used in many computing devices to provide non-volatile storage. Disk drives however use a lot of power when compared to flash memory since a disk drive needs to spin its disks at a relatively high speed and move disk heads relative to the spinning disks to read/write data. All this physical movement generates heat and increases power consumption. To this end, some higher end mobile devices are migrating towards flash memory devices that are non-volatile. However, flash memory has a number of drawbacks including, for example, relatively large voltage level requirement to change bit states, delay in write times due to requirement of a charge pump ramp up, having to erase a block of cells at a time, etc.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIGS. 1, 6, and 7 illustrate block diagrams of embodiments of computing systems, which may be utilized to implement various embodiments discussed herein.

FIG. 2 illustrates a block diagram of components that may be used to translate between SMA and PCMS addresses, according to some embodiments.

FIG. 3 illustrates portions of a storage system, according to an embodiment.

FIG. 4 shows an address multiplier logic according to an embodiment.

FIG. 5 illustrates data layout on two PCMS dies, according to an embodiment.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Phase Change Memory With Switch (PCMS) is another type of non-volatile memory that may provide higher performance and/or endurance when compared to a flash memory device. For example, PCMS allows a single bit to be changed without needing to first erase an entire block of cells, PCMS structure may degrade more slowly, PCMS data state may be retrained for a relatively longer period, and PCMS is more scalable.

Some embodiments relate to management and/or support of metadata for PCMS devices. The embodiments discussed herein are however not limited to PCMS and may be applied to any type of write in-place non-volatile memory such as Phase Change Memory (PCM). Accordingly, the terms “PCMS” and “PCM” may be interchangeable herein. In an embodiment, PCMS device accesses are translated through an Address Indirection Table (AIT). In addition to the translation to PCMS addresses, the AIT table may provide storage for metadata information, e.g., as applicable to the translation. The metadata may include information regarding the type and use of the data being referenced in PCMS, e.g., to help in managing the PCMS device.

In some embodiments, certain specific uses of PCMS improve the performance of storage solutions using the unique capabilities provided by PCMS (e.g., its load/store capabilities). For example, in a hybrid storage device, PCMS is used for metadata storage, and using the relatively cheaper NAND for data storage.

In an embodiment, metadata is used for error correction in a PCMS implementation. For example, an address calculation is performed to convert the requested data location to the device address. This flexible embodiment may be grown or adjusted depending on the basic block needed and the ECC protection level required.

In some embodiments, techniques for provision of atomic metadata support for PCMS disk caches are provided. For disk caching, use of atomic metadata may address power failure issues with write back caching Atomic metadata in this context is defined as n bytes of cache algorithm metadata that is stored along with m bytes of user data that the NVM media ensures is written in a power fail safe manner.

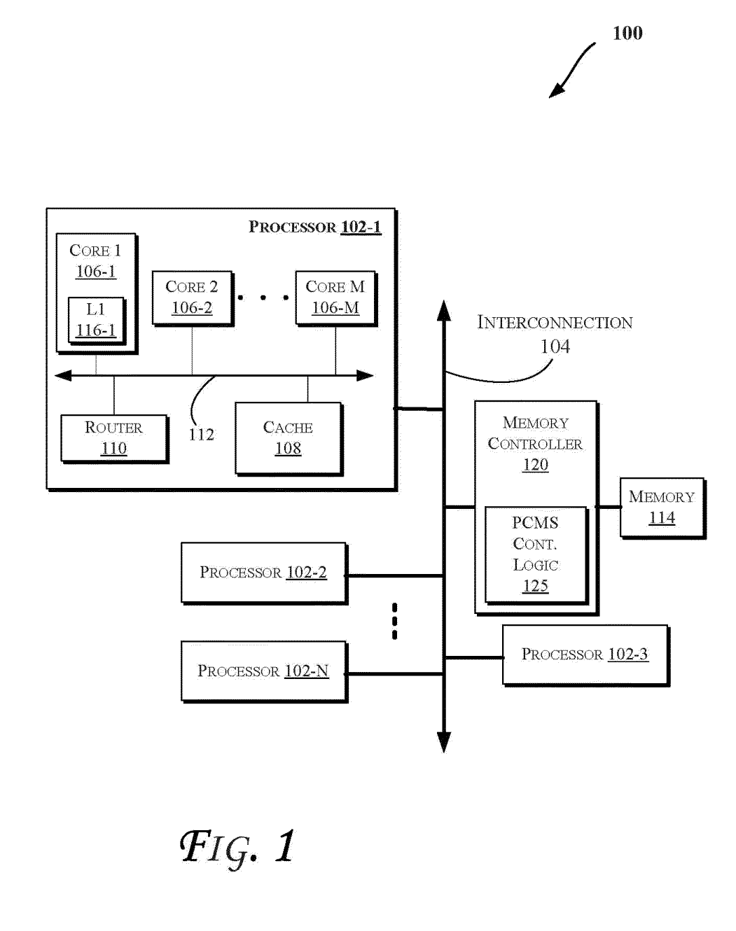

Moreover, the memory techniques discussed herein may be provided in various computing systems (e.g., including smart phones, tablets, portable game consoles, Ultra-Mobile Personal Computers (UMPCs), etc.), such as those discussed with reference to FIGS. 1-7. More particularly, FIG. 1 illustrates a block diagram of a computing system 100, according to an embodiment of the invention. The system 100 may include one or more processors 102-1 through 102-N (generally referred to herein as “processors 102” or “processor 102”). The processors 102 may communicate via an interconnection or bus 104. Each processor may include various components some of which are only discussed with reference to processor 102-1 for clarity. Accordingly, each of the remaining processors 102-2 through 102-N may include the same or similar components discussed with reference to the processor 102-1.

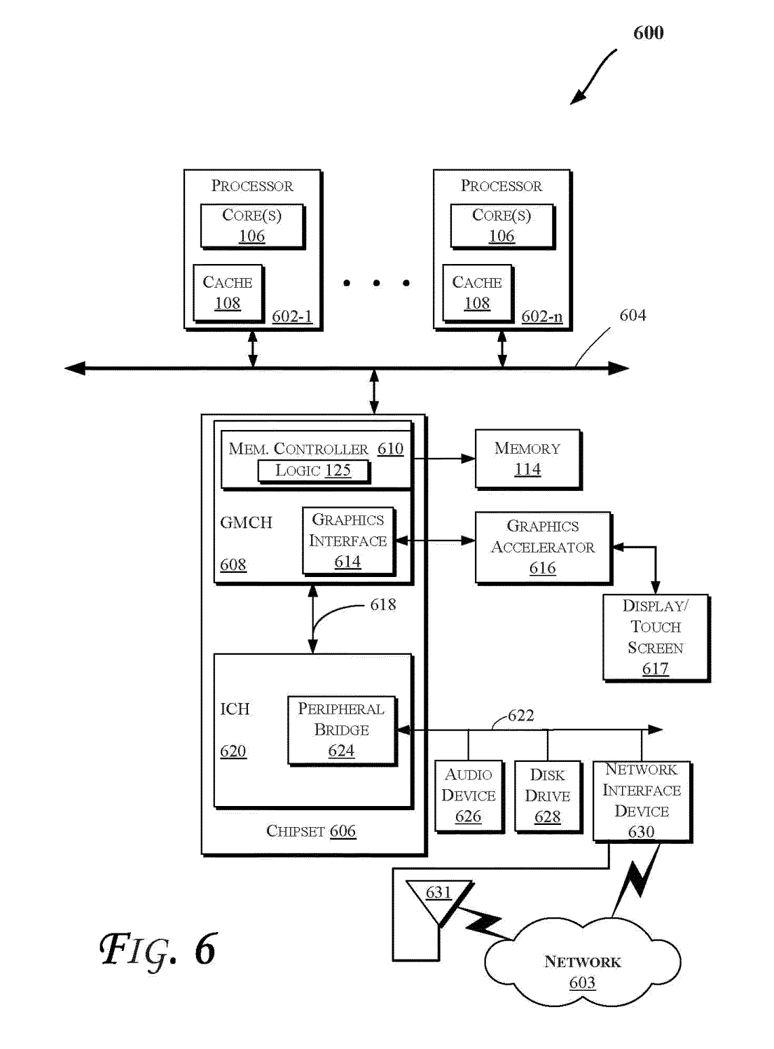

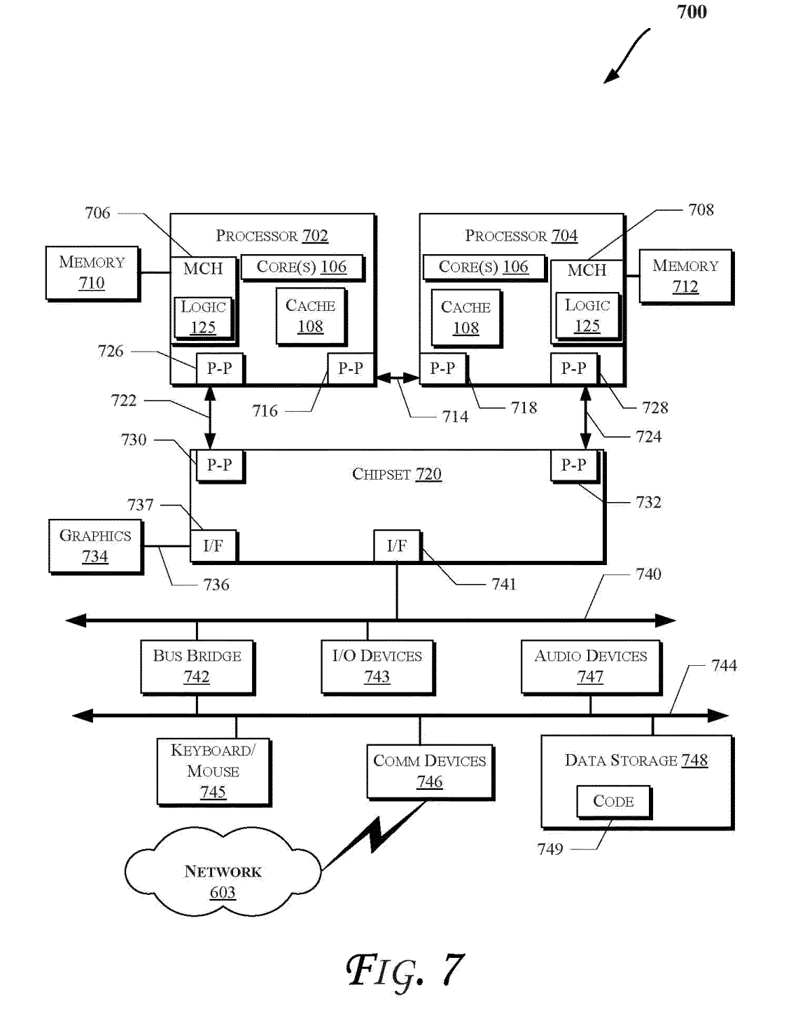

In an embodiment, the processor 102-1 may include one or more processor cores 106-1 through 106-M (referred to herein as “cores 106,” or more generally as “core 106”), a cache 108 (which may be a shared cache or a private cache in various embodiments), and/or a router 110. The processor cores 106 may be implemented on a single integrated circuit (IC) chip. Moreover, the chip may include one or more shared and/or private caches (such as cache 108), buses or interconnections (such as a bus or interconnection 112), memory controllers (such as those discussed with reference to FIGS. 6-7), or other components.

In one embodiment, the router 110 may be used to communicate between various components of the processor 102-1 and/or system 100. Moreover, the processor 102-1 may include more than one router 110. Furthermore, the multitude of routers 110 may be in communication to enable data routing between various components inside or outside of the processor 102-1.

The cache 108 may store data (e.g., including instructions) that are utilized by one or more components of the processor 102-1, such as the cores 106. For example, the cache 108 may locally cache data stored in a memory 114 for faster access by the components of the processor 102. As shown in FIG. 1, the memory 114 may be in communication with the processors 102 via the interconnection 104. In an embodiment, the cache 108 (that may be shared) may have various levels, for example, the cache 108 may be a mid-level cache and/or a last-level cache (LLC). Also, each of the cores 106 may include a level 1 (L1) cache (116-1) (generally referred to herein as “L1 cache 116”). Various components of the processor 102-1 may communicate with the cache 108 directly, through a bus (e.g., the bus 112), and/or a memory controller or hub.

As shown in FIG. 1, memory 114 may be coupled to other components of system 100 through a memory controller 120. Memory 114 may include non-volatile memory such as PCMS memory in some embodiments. Even though the memory controller 120 is shown to be coupled between the interconnection 102 and the memory 114, the memory controller 120 may be located elsewhere in system 100. For example, memory controller 120 or portions of it may be provided within one of the processors 102 in some embodiments. Also, in some embodiments, system 100 may include logic (e.g., PCMS controller logic 125) to issue read or write requests to the memory 114 in an optimal fashion.

In some embodiments, PCMS is addressable as memory but due to its device specific characteristics of limited write endurance, read drift, etc., PCMS devices may require remapping of the software generated System Memory Address (SMA) to a Non-Volatile Memory Address (NVMA) (also referred to herein as an PCMS address). An Address Indirection Table (AIT) is used in an embodiment to implement this remapping by via a controller (e.g., logic 125 of FIG. 1). In one embodiment, each entry in the AIT includes the NVM address that corresponds to the system memory address being remapped and metadata information (e.g., provided by software). The information stored in the AIT is accessed by the logic 125 to provide optimal management of the PCMS device.

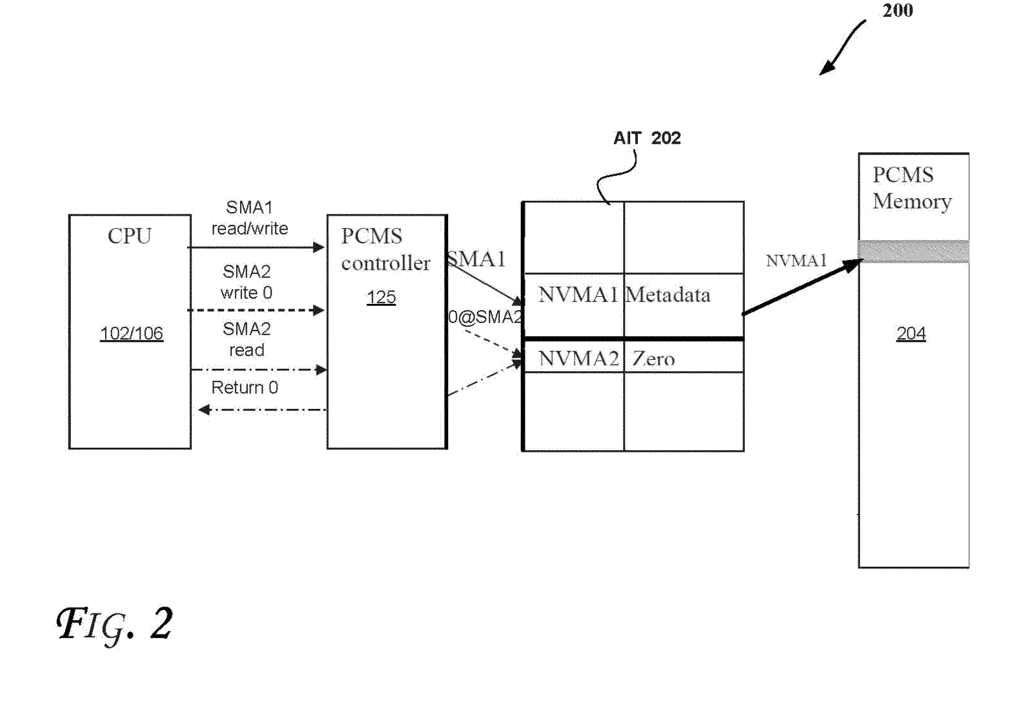

FIG. 2 illustrates a block diagram of components 200 that may be used to translate between SMA and PCMS addresses, according to some embodiments. As shown, a remap accessing NVM (SMA1) with metadata is shown in comparison with a remap of access to SMA2 write with “0” metadata and read to the same (SMA2) that avoids access to NVM/PCMS memory 204.

In an embodiment, the metadata may be provided by software using a new Instruction Set Architecture (ISA) or alternatively deduced from a current Instruction Set Architecture. The metadata information may be sent from CPU 102 (also referred to herein interchangeably as “processor”) to the PCMS controller logic 125 that remaps addresses using AIT 202. The metadata may provide the logic 125 with some semantics about the data at the NVM/PCMS address which it may use to make more optimal decisions about device management.

In accordance with some embodiments, the metadata may be:

(1) Zero—The data values to write at the NVM address are 0. This may be a new instruction in ISA to zero memory which is communicated by the CPU 102 to the controller 125 as metadata. This may be used by the controller 125 to avoid actual write to PCMS device 204 of the 0 value and thus save on the device wear and latency of subsequent reads. Instead the controller 125 has the option of returning Os when there is an access to the SMA without actually remapping it to an NVM access. Alternately, there may be NVMA with 0 data to which all AIT entries with 0 metadata are re-mapped. Since most memory state is 0, this may tremendously reduce wear in PCMS devices resulting from writing 0's.

(2) Repeated data: The data values to write at an NVM address may be repeated data values and the metadata is then this data value. The string move instructions in at least one ISA (e.g., rep movs*) may determine if the repeated value is aligned and fills the size of remap granularity and if so, store the repeated data value in the AIT 202 as metadata instead of writing the data to the PCMS device. This saves on device wear and latency for subsequent reads. The PCMS controller logic 125 may return the data pattern when the SMA is read, without actually remapping and accessing the NVMA.

(3) Read-only data: This is metadata from CPU (e.g., using page type information or with new instructions) that indicates the SMA is for read or execute only data. If the PCMS controller logic 125 implements a 2-level memory with DRAM based caching, it may use this metadata to by-pass DRAM caching and thus allow for smaller cache size dedicated for read-write SMA.

(4) Encrypted data: This metadata indicates that the data at SMA needs to be encrypted before writing it to the PCMS device.

(5) Caching priority: This metadata may be provided by supervisory mode software, e.g., using new instructions. If PCMS controller logic 125 implements a two-level memory with DRAM based caching, it may use this metadata to determine cache allocation and eviction policies.

In some embodiments, specific uses of PCMS improve the performance of storage solutions using the unique capabilities provided by PCMS (e.g., its load/store capabilities). PCMS introduces new characteristics which may be used in new ways that are different from NAND and traditional file system-based approaches. For example, in a hybrid storage device, PCMS is used for metadata storage, and using the relatively cheaper NAND for data storage.

In an embodiment, the performance of PCMS-based storage solutions may be improved for metadata operations. Also, host memory requirements may be minimized (since PCMS may be accessed directly for metadata operations, without the need for first caching the data in DRAM for example). Such embodiments may be used in PCMS-based devices that require mapping or translation (such as discussed with reference to FIG. 2, including, for example, an SSD (Solid State Drive), Peripheral Component Interface express (PCIe) storage device, or other memory devices).

Generally, in storage solutions based on PCMS, a mapping may be required where logical blocks on the front-end (e.g., in host memory) are mapped to physical blocks on the back-end (e.g., in PCMS). This mapping may be managed through metadata, which is also stored on the storage medium in an embodiment. The problem then becomes, does the design maintain the entire mapping information in memory of the host controller, or does it bring the metadata in dynamically as it is needed (when a logical block is referenced, and therefore needs the mapping). In NAND-based solutions, on-demand mapping may severely hinder performance as a block reference requires two serial NAND accesses (to fetch the metadata first and to perform the desired operation second).

On the contrary, PCMS provides the persistence of NAND, with the access methods of Random Access Memory (RAM). PCMS introduces other issues (such as the penalty box, which limits reads after a write for a short duration), but provides load/store semantics for small quanta of data.

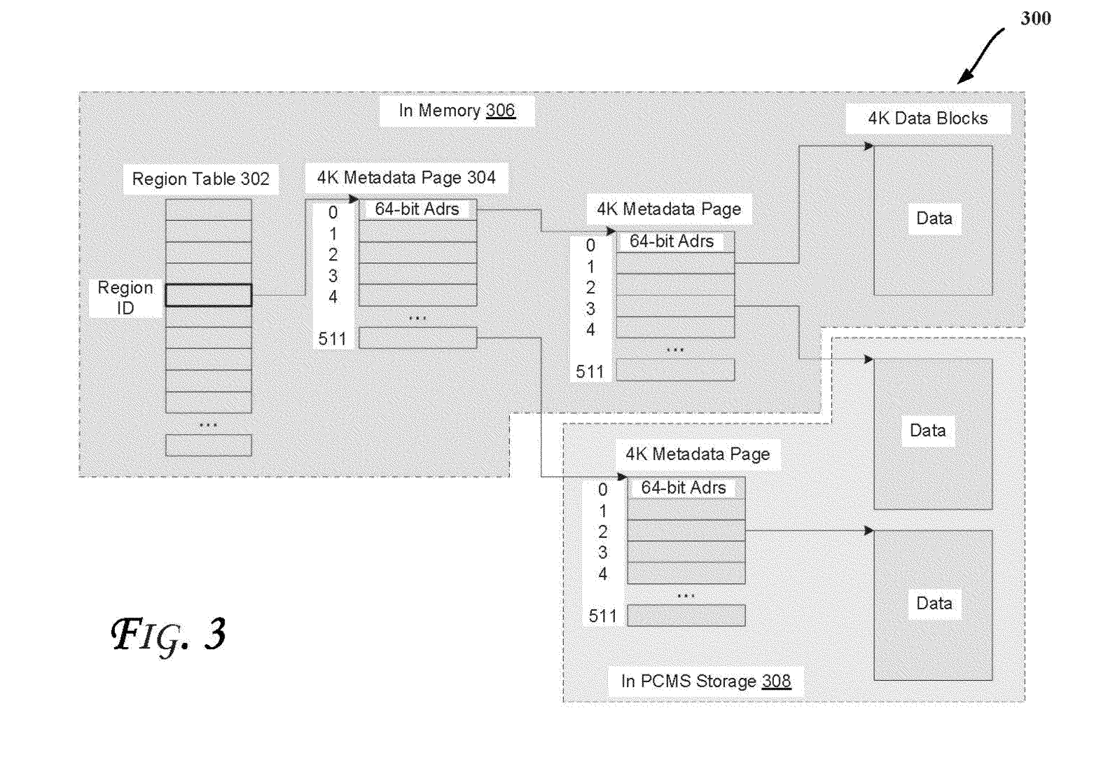

Given that PCMS may be read or written in place (i.e., without first having to cache the data in a local memory), metadata operations may be optimized for certain cases. For example, as shown in FIG. 3, a host device may maintain a region table 302, which maps regions to metadata 304 as shown. The metadata (and data) may be cached in the host memory 306, or stored within the back-end storage 308. One difference between NAND/DISK and PCMS is that with PCMS the metadata may be read in-place. This means that the metadata caching step (reading the metadata into host memory first) is not required for PCMS which reduces the latency of the read operation. Write operations could benefit from this as well, in cases where the metadata entry was not written. But given XOR-based protection within PCMS, band writes are still assumed in some embodiments, which precludes smaller writes into PCMS.

Furthermore, many NAND flash devices take the simplest approach and maintain all metadata in memory. While simple and efficient, it is costly as it adds a considerable amount of memory requirement to the host controller. This solution also does not scale well, as increasing the capacity of the back-end increases the memory requirements of the host-controller and adds additional cost.

File systems on disk-based storage devices may use on-demand metadata management (fetching metadata blocks as needed). While more efficient on host memory, this approach adds latency due to the additional accesses to the back-end. To this end, an embodiment utilizes the load/store capability of PCMS to minimize the overhead related to metadata operations (e.g., reading metadata directly from PCMS to avoid the caching operation to memory).

Referring back to FIG. 3, a sample storage system 300 that uses PCMS and a hierarchical metadata management approach is shown, according to an embodiment. The top section identifies those structures and data that exist in host memory, and the bottom section identifies those structures and data that exist in PCMS. As shown, in-memory structures reference in-memory structures and data, as well as in PCMS structures and data. As illustrated, in-PCMS structure does not refer to an in-memory structure or data. For the given region shown, the root-level metadata page may refer to data or other metadata pages (e.g., for a given block sequence). The contents of a metadata page may therefore reference to other metadata pages (e.g., in a hierarchical fashion to support large region sizes) or direct data page references. Also, while 4k pages are shown in FIG. 3, other page sizes may be used in various embodiments.

With NAND technologies, there is often a requirement to provide additional device metadata to be used for error correction. This is not the case with PCMS. As a result, the PCMS device may implement a “sea of bits”. However, accesses to the PCMS device still have a probability of error which needs correction. To this end, an embodiment allows the metadata for error correction to be used in the “sea of bits” PCMS implementation.

Generally, error correction requires that additional metadata be supplied with the data (being corrected) to check and correct as needed. As a result, a request of 64 bytes of data may have to be converted into a request of 80 bytes for the necessary detection and correction requirements. For NAND devices, additional metadata storage may be provided in the device, so no special addressing is required. Likewise for DRAM, additional bits may be added to the access width (going from 64 bits wide accesses to 72 bits wide, for example) to provide ECC (Error Correcting Code). One problem is that PCMS is merely a sea of bits and there are no special storage locations for this information. As a result, the additional storage needs to be taken from the overall capacity of a system.

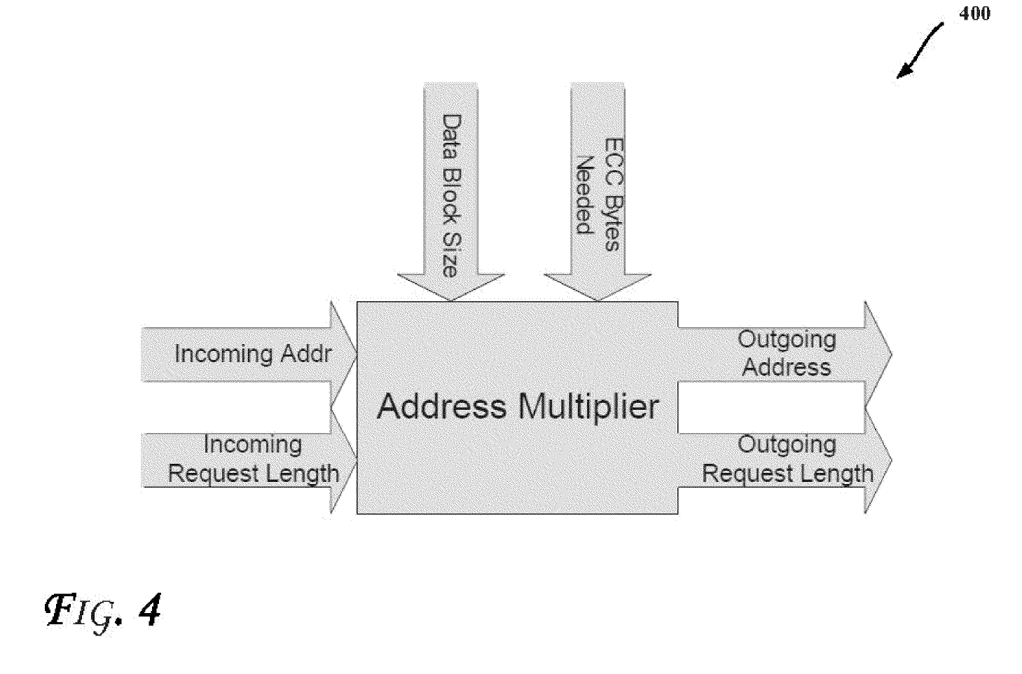

In an embodiment, an address calculation is performed to convert the requested data location to the device address (see, e.g., FIG. 4 where an address multiplier logic 400 is shown according to an embodiment). As shown in FIG. 4, the address calculation may be performed by an arithmetic conversion (e.g., which may be done by separate logic or logic within the controller logic 125). This flexible ECC embodiment may be grown or adjusted depending on the basic block needed and the ECC protection level required. Other implementation may fix this at implementation time.

Referring to FIG. 4, an Outgoing Address is determined by multiplying an Incoming Address by (Data Block Size+ECC Bytes Needed)/Data Block Size. Also, an Outgoing Request Length is determined by multiplying an Incoming Request Length by (Data Block Size+ECC Bytes Needed)/Data Block Size.

Accordingly, the address and data size of the request may be changed to provide the ECC information in line with the data transfer. As an illustration, start with the following assumptions:

Basic data block size=128 bytes

ECC needed for the 128 data payload=16 bytes

Given an incoming block address of A, the address is multiplied by the ratio of (data+metadata)/data bytes, or in this case 9/8. This may always be done as a shift and add of the address. The 128 byte request is extended by the same ratio, or in this case, to 144 bytes. If the address A coming into the device would be, say, 0xAAAA80, the resultant device address would be 9/8 * A=0xBFFFD0, and the access to the device would be from 0xBFFFD0 thru 0xC0005F, inclusive.

In some embodiments, techniques for provision of atomic metadata support for PCMS disk caches are provided. For disk caching, use of atomic metadata may address power failure issues with write back caching Atomic metadata in this context is defined as n bytes of cache algorithm metadata that is stored along with m bytes of user data that the NVM media ensures is written in a power fail safe manner.

With NAND devices, one solution is to reserve some spare area in a NAND page (atomic write unit for NAND) for metadata use. Since PCMS generally does not support the same concept of a page, a different solution needs to be employed. To this end, in an embodiment, enough capacitance and buffering may be designed into the design such that both the user data and metadata are atomically written to the PCMS media. To do this, the controller logic 125 first transfers both the data and metadata into a buffer (a buffer internal to the controller logic, for example). Once completed, the controller logic 125 starts the write operation to the PCMS media. If a power failure occurs while the write operation is in progress, the onboard capacitance continues to power the PCMS device until the write operation is complete.

While the embodiment described above is sufficient for enterprise application needing atomic metadata, e.g., per 512 byte sector such as supporting T10 Data Integrity Feature (DIF), e.g., in accordance with the guidelines promulgated by the T10 Technical Committee of the International Committee on Information Technology Standards, for low-cost client cache applications, another embodiment provides a lower cost technique. Moreover, client caches typically use metadata on cache line or frame boundaries (e.g., 8K for example), and while the previously mentioned solutions could be used to provide atomic metadata, they may be sub-optimal in terms of performance and/or cost in some situations.

Furthermore, the user data size that the metadata protects may be limited to ensure good service time and to minimize buffering and capacitance in the storage disk (e.g., SSD). For example, 16 bytes of metadata may be provided for every 512 bytes of user data. While this is one likely solution for enterprise applications needing atomic metadata (support for T10 DIF, for example) for low-cost client cache, the added overhead of 16 bytes per 512 bytes of user data may be cost-prohibitive. For these low cost solutions, where it is desired to pay less metadata overhead, metadata may be spread across a larger amounts of user data. To this end, another embodiment formats the user data with metadata at the start of the write operation and a redundant copy of metadata at the end of the write operation. As an example, the cache policies may use 16 bytes of metadata for every 8K of user data. On the PCMS SSD, this 8K of user data is then striped as two 4K write operations to 2 PCMS devices (e.g., which may be on the same die or two different dies) for increased write performance.

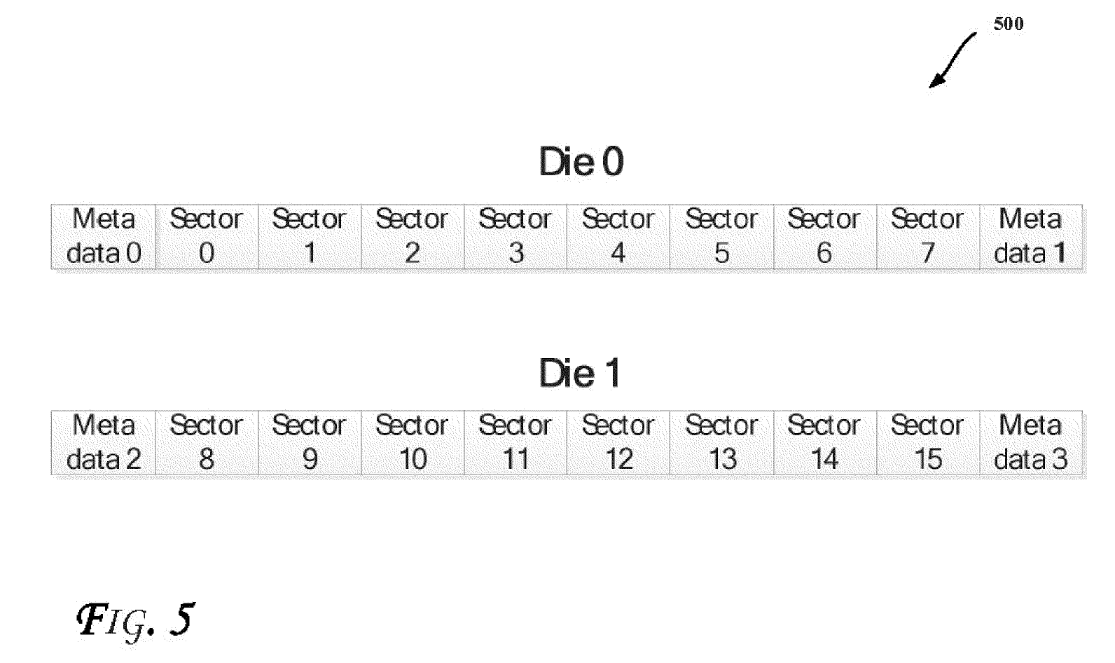

Referring to FIG. 5, a data layout on two PCMS dies is shown, according to an embodiment. Using this layout and pseudo codes below, the controller logic 125 writes, for example, both the 8K of user data and 16 bytes of metadata to the NVM media. Because the metadata is written before and after the user data, the controller logic 125 does not need to have either the buffer space or capacitance to buffer the entire 8K of user data. Instead, it may size the buffer and capacitance to the most cost effective size. Additionally, on subsequent read operation, the controller logic 125 may use the below techniques to determine if the metadata and data were written atomically.

In an embodiment, the following pseudo code may be used for writing atomic metadata:

1. Set Metadata 1 and 3 to all zeros

2. In parallel, write metadata 0 and metadata 2 to dies 0 and 1, respectively

3. In parallel, write sectors 0-7 and 8-15 to dies 0 and 1, respectively

4. In parallel, write metadata 1 and 3 to dies 0 and 1, respectively

In an embodiment, the following pseudo code may be used for determining if both data and metadata were written atomically:

1. Read metadata 0,1,2,3

2. If (metadata 0==metadata 1==metadata 2==metadata 3), return user data and metadata

3. Else return power failed during write data in sectors 0-15 inconsistent

FIG. 6 illustrates a block diagram of a computing system 600 in accordance with an embodiment of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), an application processor (such as those used in cell phones, smart phones, etc.), or other types of a processor (including a reduced instruction set computer (RISC) processor or a complex instruction set computer (CISC)). Various types of computer networks 803 may be utilized including wired (e.g., Ethernet, Gigabit, Fiber, etc.) or wireless networks (such as cellular, 3G (Third-Generation Cell-Phone Technology or 3rd Generation Wireless Format (UWCC)), 4G, Low Power Embedded (LPE), etc.). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors.

In an embodiment, one or more of the processors 602 may be the same or similar to the processors 102 of FIG. 1. For example, one or more of the processors 602 may include one or more of the cores 106 and/or cache 108. Also, the operations discussed with reference to FIGS. 1-5 may be performed by one or more components of the system 600.

A chipset 606 may also communicate with the interconnection network 604. The chipset 606 may include a graphics and memory control hub (GMCH) 608. The GMCH 608 may include a memory controller 610 (which may be the same or similar to the memory controller 120 of FIG. 1 in an embodiment, e.g., including the logic 125) that communicates with the memory 114. The memory 114 may store data, including sequences of instructions that are executed by the CPU 602, or any other device included in the computing system 600. In one embodiment of the invention, the memory 114 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple CPUs and/or multiple system memories.

The GMCH 608 may also include a graphics interface 614 that communicates with a graphics accelerator 616. In one embodiment of the invention, the graphics interface 614 may communicate with the graphics accelerator 616 via an accelerated graphics port (AGP). In an embodiment of the invention, a display 617 (such as a flat panel display, touch screen, etc.) may communicate with the graphics interface 614 through, for example, a signal converter that translates a digital representation of an image stored in a storage device such as video memory or system memory into display signals that are interpreted and displayed by the display. The display signals produced by the display device may pass through various control devices before being interpreted by and subsequently displayed on the display 617.

A hub interface 618 may allow the GMCH 608 and an input/output control hub (ICH) 620 to communicate. The ICH 620 may provide an interface to I/O devices that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603, e.g., via a wired or wireless interface). As shown, the network interface device 630 may be coupled to an antenna 631 to wirelessly (e.g., via an Institute of Electrical and Electronics Engineers (IEEE) 802.11 interface (including IEEE 802.11a/b/g/n, etc.), cellular interface, 3G, 4G, LPE, etc.) communicate with the network 603. Other devices may communicate via the bus 622. Also, various components (such as the network interface device 630) may communicate with the GMCH 608 in some embodiments of the invention. In addition, the processor 602 and the GMCH 608 may be combined to form a single chip. Furthermore, the graphics accelerator 616 may be included within the GMCH 608 in other embodiments of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

FIG. 7 illustrates a computing system 700 that is arranged in a point-to-point (PtP) configuration, according to an embodiment of the invention. In particular, FIG. 7 shows a system where processors, memory, and input/output devices are interconnected by a number of point-to-point interfaces. The operations discussed with reference to FIGS. 1-6 may be performed by one or more components of the system 700.

As illustrated in FIG. 7, the system 700 may include several processors, of which only two, processors 702 and 704 are shown for clarity. The processors 702 and 704 may each include a local memory controller hub (MCH) 706 and 708 to enable communication with memories 710 and 712. The memories 710 and/or 712 may store various data such as those discussed with reference to the memory 114 of FIGS. 1 and/or 6. Also, MCH 706 and 708 may include the memory controller 120 and/or logic 125 of FIG. 1 in some embodiments.

In an embodiment, the processors 702 and 704 may be one of the processors 602 discussed with reference to FIG. 6. The processors 702 and 704 may exchange data via a point-to-point (PtP) interface 714 using PtP interface circuits 716 and 718, respectively. Also, the processors 702 and 704 may each exchange data with a chipset 720 via individual PtP interfaces 722 and 724 using point-to-point interface circuits 726, 728, 730, and 732. The chipset 720 may further exchange data with a high-performance graphics circuit 734 via a high-performance graphics interface 736, e.g., using a PtP interface circuit 737. As discussed with reference to FIG. 6, the graphics interface 736 may be coupled to a display device (e.g., display 617) in some embodiments.

As shown in FIG. 7, one or more of the cores 106 and/or cache 108 of FIG. 1 may be located within the processors 702 and 704. Other embodiments of the invention, however, may exist in other circuits, logic units, or devices within the system 700 of FIG. 7. Furthermore, other embodiments of the invention may be distributed throughout several circuits, logic units, or devices illustrated in FIG. 7.

The chipset 720 may communicate with a bus 740 using a PtP interface circuit 741. The bus 740 may have one or more devices that communicate with it, such as a bus bridge 742 and I/O devices 743. Via a bus 744, the bus bridge 743 may communicate with other devices such as a keyboard/mouse 745, communication devices 746 (such as modems, network interface devices, or other communication devices that may communicate with the computer network 603, as discussed with reference to network interface device 630 for example, including via antenna 631), audio I/O device, and/or a data storage device 748. The data storage device 748 may store code 749 that may be executed by the processors 702 and/or 704.

In various embodiments of the invention, the operations discussed herein, e.g., with reference to FIGS. 1-7, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed with respect to FIGS. 1-7.

Additionally, such tangible computer-readable media may be downloaded as a computer program product, wherein the program may be transferred from a remote computer (e.g., a server) to a requesting computer (e.g., a client) by way of data signals (such as in a carrier wave or other propagation medium) via a communication link (e.g., a bus, a modem, or a network connection).

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1-30. (canceled)

31. An apparatus comprising:
Phase Change Memory (PCM) controller logic to control access to a PCM device; and
memory to store an Address Indirect Table (AIT),
wherein the AIT is to store information to translate between system memory addresses and PCM addresses,
wherein the AIT table is to comprise metadata corresponding to a type of data stored in the PCM device, and
wherein the PCM controller logic is to provide access to the PCM device based on the information stored in the AIT.

32. The apparatus of claim 31, wherein the metadata is to provide the PCM controller logic with information about data stored in the PCM device to permit the PCM controller logic to respond to a request from a processor without having to first access the PCM device.

33. The apparatus of claim 31, wherein the metadata is one of: zero, repeated data, read-only data, encrypted data, and caching priority.

34. The apparatus of claim 31, wherein a processor is to transmit the metadata to the PCM controller logic.

35. The apparatus of claim 31, wherein the metadata is to be provided in thorough an instruction.

36. The apparatus of claim 31, wherein one or more of the PCM controller logic, memory, PCM device, and a processor core are on a same integrated circuit die.

37. An apparatus comprising:
Phase Change Memory (PCM) controller logic to control access to a PCM device; and
host memory to store a region table to map memory regions to metadata, wherein the PCM controller logic is to provide access to the PCM device based on direct reading of the metadata stored in the PCM device.

38. The apparatus of claim 37, wherein at least a portion of the metadata is to be stored in the host memory.

39. The apparatus of claim 37, wherein one or more structures stored in the host memory are to reference one or more other structures and data stored in the host memory and/or one or more structures and data stored in the MCMS device.

40. The apparatus of claim 37, wherein one or more structures stored in the PCM device are to only reference one or more other structures and data stored in the PCM device.

41. The apparatus of claim 37, wherein one or more of the PCM controller logic, host memory, PCM device, and a processor core are on a same integrated circuit die.

42. An apparatus comprising:
Phase Change Memory with Switch (PCM) controller logic to control access to a PCM device; and
logic to determine an outgoing address and an outgoing request length corresponding to error correction metadata stored in the PCM device.

43. The apparatus of claim 42, wherein the logic is to determine the outgoing address based on an incoming address, a data block size, and a number of bytes for an Error or Correcting Code (ECC).

44. The apparatus of claim 42, wherein the logic is to determine the outgoing request length based on an incoming request length, a data block size, and a number of bytes for an Error Correcting Code (ECC).

45. The apparatus of claim 42, wherein the PCM controller logic is to comprise the logic to determine the outgoing address and the outgoing request length.

46. The apparatus of claim 42, wherein one or more of the PCM controller logic, logic to determine the outgoing address and the outgoing request length, PCM device, and a processor core are on a same integrated circuit die.

47. An apparatus comprising:
Phase Change Memory (PCM) controller logic to control access to a PCM device,
wherein the PCM controller logic is to write data to the PCM device after storing the data and metadata to a buffer.

48. The apparatus of claim 47, wherein the metadata is to be used in case of loss of the data.

49. The apparatus of claim 47, wherein one or more of the PCM controller logic, PCM device, and a processor core are on a same integrated circuit die.

50. An apparatus comprising:
one or more Phase Change Memory (PCM) controller logic to control access to one or more of a first PCM die and a second PCM die, wherein the one or more PCM controller logic are to write a first a first data set, having at least two copies of a first metadata, to the first PCM die.

51. The apparatus of claim 50, wherein the one or more PCM controller logic are to write a second data set, having at least two copies of a second metadata, to the second PCM die.

52. The apparatus of claim 51, wherein the second data set is to comprise in order the second metadata, a second user data, and a redundant copy of the second metadata.

53. A system comprising:
a PCM device;
a processor to access data stored on the PCM device via a PCM controller logic; and
memory to store metadata corresponding to the data stored on the PCM device,
wherein the PCM controller logic is to allow access to the PCM device based on the metadata.

54. The system of claim 53, wherein the memory is to store an Address Indirect Table (AIT), wherein the AIT is to store information to translate between system memory addresses and PCM addresses and wherein the AIT table is to comprise the metadata, corresponding to a type of data stored in the PCM device, and wherein the PCM controller logic is to provide access to the PCM device based on the information stored in the AIT.

55. The system of claim 53, wherein the memory is to comprise host memory to store a region table to map memory regions to the metadata.
